(19) United States
(12) Patent Application Publication
(10) Pub. No.: US 2014/0144484 A1
(43) Pub. Date: May 29, 2014

(54) Hinge for Solar Tracking Apparatus

(71) Applicant: Kiran Shah, Pune (IN)

(72) Inventor: Kiran Shah, Pune (IN)

(73) Assignee: SCORPIUS TRACKERS PRIVATE LIMITED, Pune, Maharashtra (IN)

(21) Appl. No.: 14/128,812

(22) PCT Filed: Jun. 22, 2012
(86) PCT No.: PCT/IN2012/000448

§ 371 Date: Dec. 23, 2013

(30) Foreign Application Priority Data
Jun. 24, 2011 (IN) 1826/MUM/2011

(51) Int. Cl. H01L 31/042; H01L 31/052

(52) U.S. Cl. CPC H01L 31/0422; H01L 31/052
USPC 136/246; 248/274.1

(57) ABSTRACT

A hinge for solar tracking apparatus is disclosed. The hinge includes a first mounting plate, a second mounting plate and a plurality of connecting elements. The first mounting plate has a pair of beveled or curved side faces. The second mounting plate has a pair of beveled or curved side faces. The plurality of connecting elements connect the first mounting plate to the second mounting plate in a spaced apart configuration, wherein each of the plurality of connecting elements connects diagonally opposite side faces of the first mounting plate to the second mounting plate. The hinge facilitates the solar tracking apparatus to track the Sun.

### FIELD OF THE DISCLOSURE

The present disclosure generally relates to systems and methods used for generating solar power.

Particularly, the present disclosure relates to a hinge/pivot for solar tracking apparatus for facilitating generation of solar power.

### BACKGROUND

A solar panel (photo-voltaic module or photo-voltaic panel) is a packaged inter-connected assembly of solar cells that can be used for generating and supplying electricity for commercial and residential applications. However, regardless of the type of solar panel being used, efficient energy production by a solar panel is dependent on orientation and position of the solar panel with respect to the Sun. More specifically, for efficient energy production from a solar panel, orientation of the solar panel should be such that the solar panel is continuously exposed to solar radiations, i.e. the solar panel is continuously facing the Sun. However, the position of the Sun keeps on changing as the day advances. So in order to keep a solar panel in a desired orientation with respect to the Sun, the solar panel is required to be oriented at a speed such that the solar panel is pointed at the Sun and is tracking the changing position of the Sun. Such a task is accomplished by a solar tracker and a pivot connecting a solar panel to the frame of the solar tracker.

A solar tracker along with a solar panel mounted thereon follows the Sun as the Sun changes its position as the day advances, thereby enabling the solar panel to remain in desired orientation with respect to the Sun for maximum utilization of solar radiations. Accordingly, use of a solar tracker is beneficial for higher generation of solar power. A large variety of solar tracking devices are available in the prior art. But most of the solar tracking devices are complex in construction and require large number of moving parts and are expensive.

For example, an altazimuth mount is a two-axis mount for supporting and rotating a structure about two mutually perpendicular axes, one vertical and other horizontal. Rotation about the vertical axis varies an azimuth (compass bearing) of the pointing direction of the structure. Rotation about the horizontal axis varies an altitude (angle of elevation) of the pointing direction. However, altazimuth mounts need to be driven about both axes at variable rates, achieved via micro-processor based two-axis drive systems, to track equatorial motion. Driving mechanisms of altazimuth mounts include gears or belts that are difficult to manufacture precisely. Also, rotating elements comprising of shafts and conventional roller bearings have slop, friction and hysterisis imparting an uneven rotation to the mount. Further, driving mechanisms also require regular maintenance. Accordingly, use of such driving mechanisms in altazimuth mounts for tracking solar panel is expensive and leads to inaccuracies.

Further, an equatorial mount is a mount for structures or instruments, like telescopes and solar panels that follows rotation of the sky by having one rotational axis parallel to the Earth's axis of rotation. An equatorial mount facilitates a structure or an instrument attached thereto to stay fixed on any object in the sky that has a diurnal motion by driving one axis at a constant speed. Such an arrangement is called a sidereal drive. In equatorial mounts, an equatorial axis also called right ascension is paired with a second perpendicular axis of motion known as a declination axis. An equatorial axis of an equatorial mount is equipped with a motorized clock drive that rotates the axis one revolution every 23 hours 56 minutes and 4 seconds in exact sync with the diurnal motion of the sky. Equatorial mounts differ from altazimuth mounts, which requires variable speed motion around both axes to track a fixed object in the sky. Due to their design, their construction is massive and requires large amount of material for constructing a mount. Further, equatorial mounts are able to carry less mass as compared to altazimuth mounts in addition to having errors due to use of conventional bearings, gears and drives in their construction

However, most of the above mentioned astronomical tracking devices known in the prior art require regular maintenance, more specifically, the above mentioned astronomical tracking devices fail to accurately track the astronomical entities without any play or require expensive and complex mechanisms to reduce play.

Some of the prior art patent documents are as follows:

For example, US Publication Number US20110180057 discloses solar collectors mounted on an elevation-azimuth tracking structure, supported and articulated to follow movement of the sun. The solar collectors include an inflatable concentrator system. The inflatable concentrator system includes a replaceable cartridge including radial support rings, films and a seal ring. The seal ring may be made of a compliant material so that it maintains tight contact with films, or it may be adhered to the optical films with adhesive or it may be heat sealed to the films. Also, a layer of compliant material may be used to distribute forces between structural elements and the optical film. However, the elevation-azimuth tracking structure disclosed by the Publication Number US20110180057 is comparatively ineffective to follow the movement of the sun.

Further, US Publication No. US20100199972 discloses linear solar reflectors and collectors, and methods of efficiently constructing such reflectors and collectors. Also, methods and apparatuses for installing the sheets from a roll dispensing the sheets carried on a deployment vehicle, as well as methods and apparatuses for assembling and constructing various collector components are disclosed. A curvature-adjustment system for adjustment of curvature of a mirror of a linear solar reflector supported by a rib pivotally attached to a horizontal support rod at a pivot point in response to movement of the rib by an actuator to track the sun throughout the day is also disclosed. The curvature-adjustment system includes a compliant mirror support and a mechanism. The compliant mirror support is flexible and can bend through a range of desired curvatures for the linear solar reflector. The mechanism automatically changes the curvature of the compliant mirror support to a desired curvature in passive response to the actuation mechanism rotating the rib to track the sun through the day. In one embodiment, the compliant mirror support has an hourglass shape contoured to provide a deflection matching the desired parabolic shape of the mirror. However, the tracking mechanism disclosed by the Publication Number US20100199972 is comparatively ineffective to follow the movement of the Sun.

Furthermore, US Publication No. US20090283133 discloses an article that is suitable for use as a solar concentrating mirror for enhancing the use of solar collection devices, such as solar cells. The article includes one or more solar cells having an absorption bandwidth; one or more compliant films positioned in proximity to the solar cell. The compliant film is a combination of (i) multilayer optical film having an optical stack having a plurality of alternating layers, the alternating layers having at least one birefringent polymer and at least one second polymer; and (ii) a UV protective layer applied onto a surface of the multilayer optical film, wherein the compliant film reflects at least a major portion of the average light across the range of wavelengths that corresponds with the absorption conversion bandwidth of the solar cell onto the solar cell and does not reflect onto the solar cell a major portion of light outside the absorption bandwidth of the solar cell. In one embodiment, the compliant film is formed in a parabolic or curved shape and the solar cell is positioned above the compliant film. However, the US Publication No. US20090283133 only discloses an article that is suitable for use as a solar concentrating mirror.

Further, accuracy of most of the prior art astronomical tracking devices is dependent on pivots/hinges used in the astronomical tracking devices. Pivot/hinge is an absolutely essential component of any astronomical tracking device and plays a critical role in accurate operation of astronomical tracking devices. Most of the astronomical tracking devices known in the prior art make use of conventional roller bearings. However, there are various limitations associated with the use of conventional roller bearings in the astronomical tracking device of the prior art. More specifically, the conventional pivots/hinges used in the astronomical tracking devices of the prior art are subjected to backlash, wear and tear, hysteresis and friction. Further, the conventional pivots used in the astronomical tracking devices of the prior art require regular maintenance and cannot be used in dusty, salty, rainy or other harsh environments.

Accordingly, there is need of a pivot/hinge for an astronomical tracking device that eliminates drawbacks associated with conventional pivots and thereby enhances accuracy of astronomical tracking devices. Further, there is need of a pivot/hinge for use in an astronomical tracking device that is simple in construction and is easy to manufacture. Furthermore, there is need of a pivot/hinge for use in an astronomical tracking device that requires no maintenance. Further, there is need of a pivot/hinge that is free from ill-effects of back-lash, hysteresis and friction.

Objects

Some of the objects of the system of the present disclosure, which at least one embodiment herein satisfies, are as follows:

It is an object of the system of the present disclosure to ameliorate one or more problems of the prior art or to at least provide a useful alternative.

An object of the system of the present disclosure is to provide a hinge for a solar tracking apparatus that enhances accuracy of a solar tracking apparatus.

Another object of the system of the present disclosure is to provide a hinge for a solar tracking apparatus that enables a solar power converter mounted on a solar tracking apparatus to accurately follow the Sun as the sun changes its position.

Also, an object of the system of the present disclosure is to provide a hinge for use in a solar tracking apparatus that is simple in construction.

Additionally, an object of the system of the present disclosure is to provide a hinge for use in a solar tracking apparatus that is free from ill-effects of back-lash, hysteresis and friction.

Moreover, an object of the system of the present disclosure is to provide a hinge for use in a solar tracking apparatus that requires insignificant maintenance and is not affected by harsh environment conditions.

Furthermore, an object of the system of the present disclosure is to provide a hinge for use in a solar tracking apparatus that is easy to manufacture.

Other objects and advantages of the system of the present disclosure will be more apparent from the following description when read in conjunction with the accompanying figures which are not intended to limit the scope of the present disclosure.

### SUMMARY

In accordance with one aspect of the present disclosure, a hinge for solar tracking apparatus is disclosed. The hinge includes a first mounting plate, a second mounting plate and a plurality of connecting elements. The first mounting plate has a pair of beveled or curved side faces. The second mounting plate has a pair of beveled or curved side faces. The plurality of connecting elements is adapted to connect said first mounting plate to the second mounting plate in a spaced apart configuration, wherein each of the plurality of connecting elements is adapted to connect diagonally opposite side faces of the first mounting plate to the second mounting plate. The hinge is adapted to facilitate the solar tracking apparatus to track the Sun.

Typically, the beveled side faces of the first mounting plate and the second mounting plate have a bevel angle of about 45°.

In one embodiment, diagonally opposite side faces of the first mounting plate and the second mounting plate have equal bevel angles.

Typically, each of the first mounting plate and the second mounting plate includes at least one mounting hole configured thereon for facilitating mounting thereof to other structural elements.

In one embodiment, each of the first mounting plate and the second mounting plate is of powder coated mild steel.

In one embodiment, each of the plurality of connecting elements is a thin discrete strip.

Alternatively, in another embodiment, each of said plurality of connecting elements has a frame structure.

In accordance with another aspect of the present disclosure, a solar power generation system is disclosed. The solar power generation system includes a solar power converter, at least one hinge and a solar tracking apparatus. The solar power converter is adapted to convert solar energy into at least one other form of energy. At least one hinge is adapted to facilitate mounting of the solar power converter thereon. Each of the at least one hinge includes a first mounting plate, a second mounting plate and a plurality of connecting elements. The first mounting plate has a pair of beveled or curved side faces. The second mounting plate has a pair of beveled or curved side faces. The plurality of connecting elements is adapted to connect the first mounting plate to the second mounting plate in a spaced apart configuration, wherein each of the plurality of connecting elements is adapted to connect diagonally opposite side faces of the first mounting plate to the second mounting plate. The solar tracking apparatus is adapted to mount at least one hinge thereon, wherein the solar tracking apparatus is adapted to facilitate tracking of the Sun by means of the at least one hinge.

Typically, the solar power converter is a solar cell for generation of electricity or a concentrating system for generation of thermal power.

### BRIEF DESCRIPTION OF ACCOMPANYING DRAWINGS

The hinge of the present disclosure will now be explained in relation to the non-limiting accompanying drawings, in which:

FIG. 1 illustrates a perspective view of a hinge for solar tracking apparatus, in one embodiment;

FIG. 2 illustrates another perspective view of the hinge of FIG. 1; and

FIG. 3 illustrates a side view of the hinge of FIG. 1;

FIG. 4 illustrates a perspective view of a solar power generation system with an equatorial tracker and the hinge of FIG. 1;

FIG. 4a illustrates an enlarged view of the hinge of FIG. 4;

FIGS. 5a and 5b illustrate perspective views of a solar power generation system with a horizontal tracker and the hinge of FIG. 1;

FIG. 6 illustrates a perspective view of the hinge of FIG. 1 without bending;

FIG. 7 illustrates a perspective view of the hinge of FIG. 1 with bending;

FIG. 8 illustrates a perspective view of the hinge of FIG. 1 stacked one above the other, without bending, for facilitating greater angle of operational deflection; and

FIG. 9 illustrates a perspective view of the hinge of FIG. 1 stacked one above the other, depicting bended configuration, for facilitating greater angle of operational deflection.

### DETAILED DESCRIPTION

The hinge for solar tracking apparatus of the present disclosure will now be described with reference to the accompanying drawings which do not limit the scope and ambit of the disclosure. The description provided is purely by way of example and illustration.

The embodiments herein and the various features and advantageous details thereof are explained with reference to the non-limiting embodiments in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The description hereinafter, of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

The present disclosure provides a hinge for a solar tracking apparatus. A hinge enhances efficiency and effectiveness of a solar tracking apparatus. A hinge is adapted to support a solar power converter and facilitate movement thereof about one or two axis by using one or more pivots for enabling the solar panel to accurately follow the Sun as the position of the Sun changes during the day.

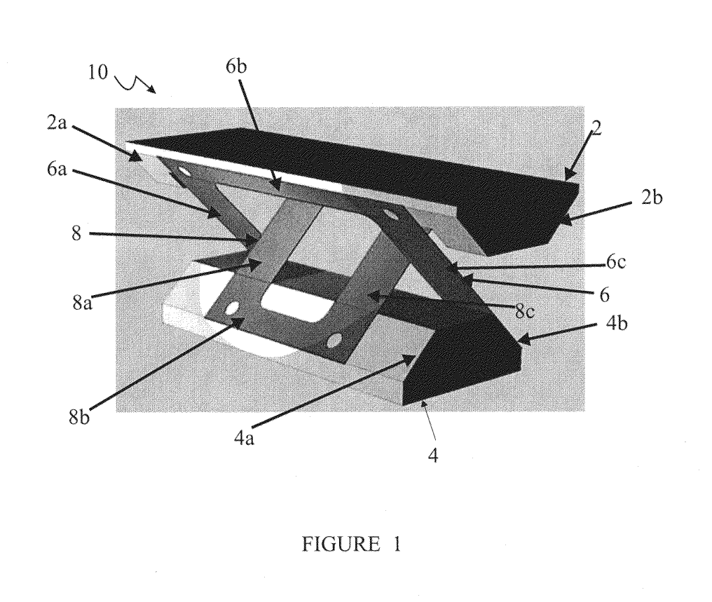

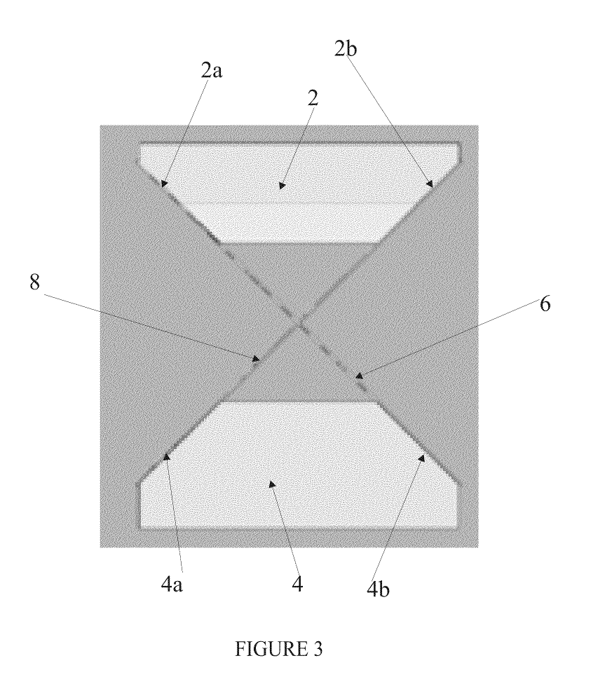

Referring to FIGS. 1 to 3 of the accompanying drawings, a hinge/pivot 10 for connecting a solar power converter (not shown) to a solar tracking apparatus (not shown) and for enabling the solar power converter to follow the sun as the sun changes its position during day-time is illustrated. The hinge 10 includes a first mounting plate 2 and a second mounting plate 4. The first mounting plate 2 includes a pair of opposing side faces 2a and 2b that are beveled, hereinafter referred to as the beveled faces 2a and 2b. The beveled faces 2a and 2b of the first mounting plate 2 are typically having a bevel angle of 45 degrees. However, the present disclosure is not limited to any particular bevel angle configured by either of the beveled faces 2a and 2b. The present disclosure is also not limited to any particular shape for the beveled faces 2a and 2b. Similarly, the second mounting plate 4 includes a pair of opposing side faces 4a and 4b that are beveled, hereinafter referred to as the beveled faces 4a and 4b. The beveled faces 4a and 4b of the second mounting plate 4 are typically having a bevel angle of 45 degrees. However, the present disclosure is not limited to any particular bevel angle configured by either of the beveled faces 4a and 4b. Also the present disclosure is also not limited to any particular shape for the beveled faces 4a and 4b. Particularly, the beveled face 4a of the second mounting plate 4 and the beveled face 2b of the first mounting plate 2 should have equal bevel angles. Particularly, the beveled face 4a of the second mounting plate 4 and the beveled face 2b of the first mounting plate 2 are said to be diagonally opposite side faces of each other. Similarly, the beveled face 4b of the second mounting plate 4 and the beveled face 2a of the first mounting plate 2 are said to be diagonally opposite side faces of each other. The beveled face 4b of the second mounting plate 4 and the beveled face 2a of the first mounting plate 2 should have equal bevel angles

Further, both the mounting plates 2 and 4 includes mounting holes configured thereon for facilitating the mounting of one of the mounting plates onto a solar tracking device while mounting the solar power converter on the other mounting plate. The mounting plates 2 and 4 are generally made from powder coated mild steel. However, the present disclosure is not limited to a particular material for configuring the mounting plates 2 and 4 or a particular surface treatment method for ensuring its resistance to corrosion. The mounting method also is not limited to using holes and bolts, but molding, brazing etc. could be used for facilitating the mounting.

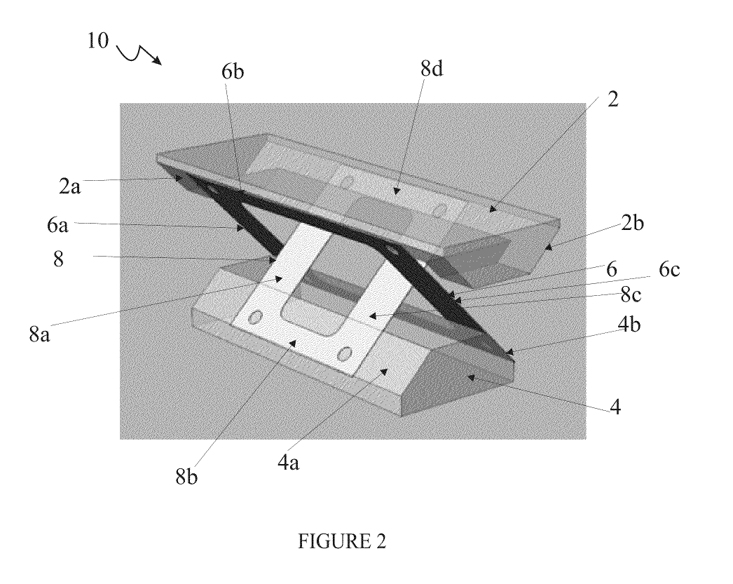

The first mounting plate 2 and the second mounting plate 4 are connected to each other in a spaced apart configuration by means of a first connecting element 6 and a second connecting element 8. The first connecting element 6 connects the beveled face 2a of the mounting plate 2 to the beveled face 4b of the mounting plate 4. Similarly, the second connecting element 8 connects the beveled face 4a of the mounting plate 4 to the beveled face 2b of the mounting plate 2. Accordingly, both the connecting elements 6 and 8 are crisscrossing each other. The first connecting element 6 may be a thin plate that is flexible and is adapted to bend when a bending moment is applied thereon. The thin plate may be provided with a wide opening for providing a frame like structure to the plate for facilitating bending there-of under action of bending moment applied at the ends. As illustrated in FIG. 1 and FIG. 2 of the accompanying drawings the plate 6 having a frame like structure includes four sides 6a, 6b, 6c and 6d. In accordance with another embodiment of the present invention the first connecting element 6 may be a pair of discrete thin strips that connect the beveled face 2a of the mounting plate 2 with the beveled face 4b of the mounting plate 4. The second connecting element 8 is structurally and functionally similar to the first connecting element 6 and for the sake of brevity of the present document is not described in details. Referring to FIG. 1 and FIG. 2 of the accompanying drawings, the plate 8 is also having a frame like structure and includes four sides 8a, 8b, 8c and 8d.

More specifically, the side 6b of the first connecting element 6 is secured to the beveled face 2a of the first mounting plate 2 by means of screws or bolts and the opposite side 6d of the first connecting element 6 is secured to the beveled face 4b of the second mounting plate 4 by means of screws or bolts. Similarly, the side 8b of the second connecting element 8 is secured to the beveled face 4a of the second mounting plate 4 by means of screws or bolts and the opposite side 8d of the second connecting element 8 is secured to the beveled face 2b of the first mounting plate 2 by means of screws or bolts. However, the present invention is not limited to a particular method for securing the first connecting element 6 and the second connecting element 8 to the first mounting plate 2 and the second mounting plate 4.

The first connecting element 6 and the second connecting element 8 are flexible and are adapted to bend when a bending moment is applied on the ends there-of resulting from the force acting on either of the mounting plates mounted on the solar tracker apparatus. The first and second connecting elements are made from any material that exhibits flexibility, resilience and ease of bending. However, the present invention is not limited to a particular material used for configuring the first and second connecting elements.

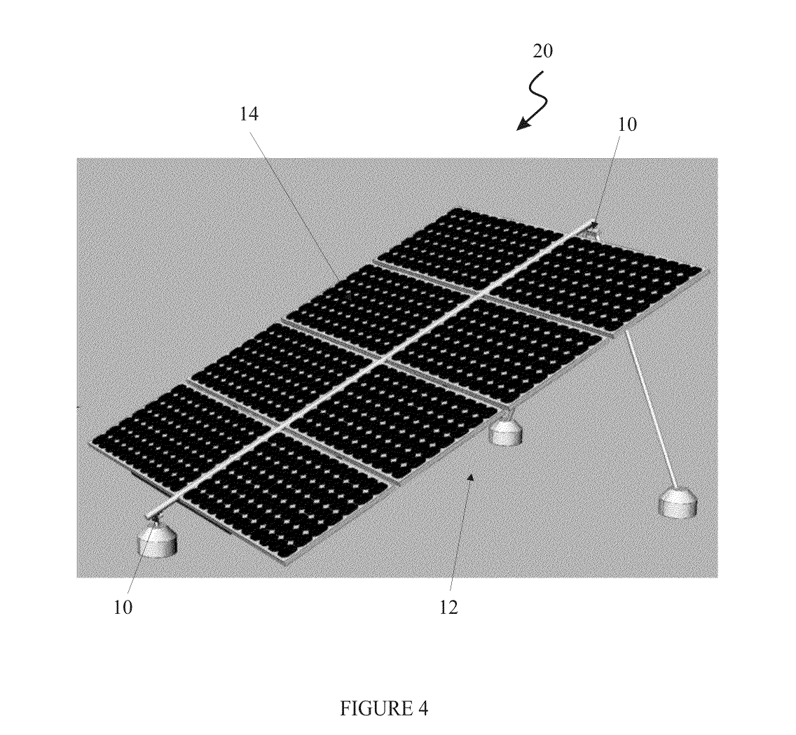

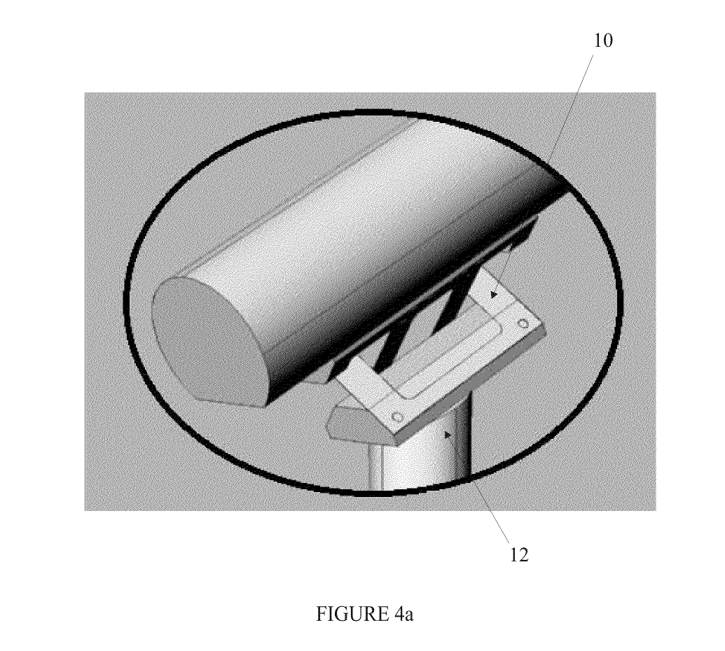

Referring to FIGS. 4 and 4a, a solar power generation system 20 is disclosed. The solar power generation system 20 includes a solar power converter 14, a hinge 10 and an equatorial tracker 12. The solar power converter 14 is adapted to convert solar energy into at least one other form of energy, such as electrical energy, thermal energy and the like. In the present embodiment, the solar power converter 14 is a solar cell. The hinge 10 is disposed on both ends of the equatorial tracker 12. One of the first mounting plate 2 and the second mounting plate 4 is disposed on the solar equatorial tracker 12 and the solar panel 14 is mounted on the other plate. The equatorial tracker 12 is adapted to facilitate tracking of the Sun by means of the hinge 10.

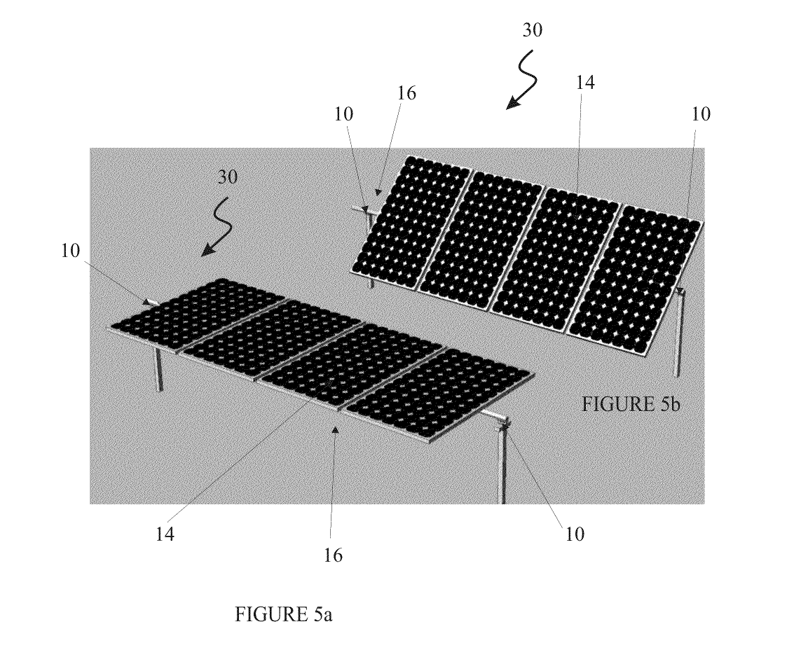

Referring to FIGS. 5a and 5b, a solar power generation system 30 is disclosed. The solar power generation system 30 includes a solar power converter 14, a hinge 10 and a horizontal tracker 16. The solar power converter 14 is adapted to convert solar energy into at least one other form of energy, such as electrical energy, thermal energy and the like. In the present embodiment, the solar power converter 14 is a solar cell. The hinge 10 is disposed on both ends of the horizontal tracker 16. One of the first mounting plate 2 and the second mounting plate 4 is disposed on the horizontal tracker 16 and the solar panel 14 is mounted on the other plate. The horizontal tracker 16 is adapted to facilitate tracking of the Sun by means of the hinge 10. FIG. 5b illustrates a tilted position of the solar panel 14 of the solar power generation system 30.

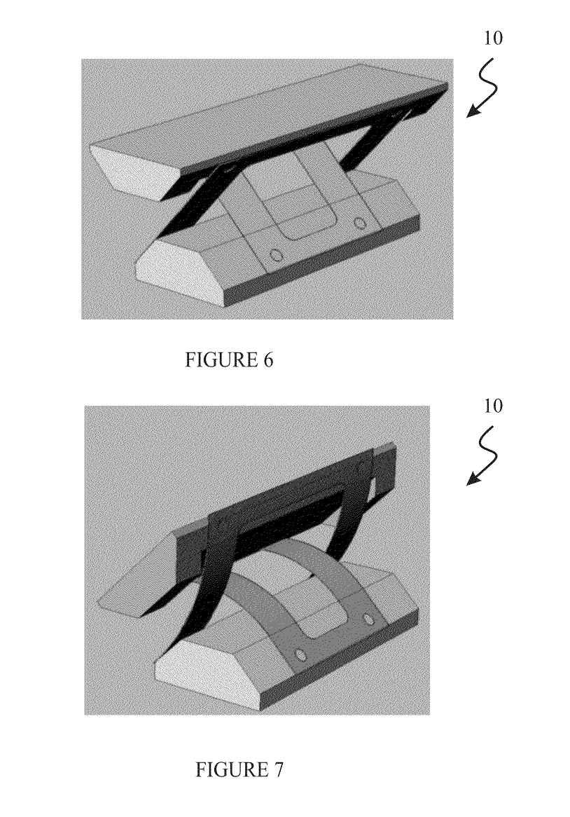

Referring to FIG. 6, a perspective view of the hinge 10 is illustrated without any bending. FIG. 7 illustrates a perspective view depicting bended position of the hinge 10. The bended configuration of the hinge 10 is configured during tracking the movements of the Sun. The bended configuration of the hinge 10 is activated by a solar tracking apparatus such as the equatorial tracker 12, the horizontal tracker 16 and the like, during tracking the movements of the Sun.

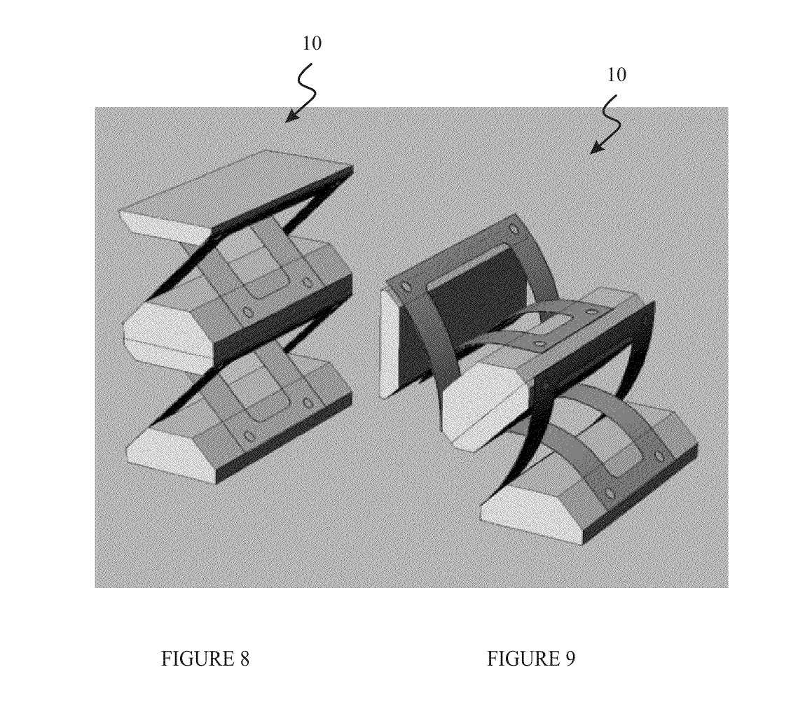

As shown, in FIGS. 8 and 9, the hinges 10 are stacked one above another for providing increased angle of operational deflection. For example, if the safe angular deflection provided by the one hinge is 45°, than stacking of another hinge over the first hinge will provide total effective angular deflection of 90°. Accordingly, stacking of hinges one above another facilitates increased angle of operational deflection.

Technical Advancements of Economical Significance

The technical advancements offered by the system of the present disclosure which add to the economic significance of the disclosure include the realization of:
a hinge for a solar tracking apparatus that enhances accuracy of the solar tracking apparatus;
a hinge for a solar tracking apparatus that enables a solar power converter mounted on a solar tracking apparatus to accurately follow the Sun as the sun changes its positions;
a hinge for use in a solar tracking apparatus that is simple in construction;
a hinge for use in a solar tracking apparatus that is free from ill-effects of back-lash, hysteresis and friction;
a hinge for use in a solar tracking apparatus that requires insignificant maintenance and is not affected by harsh environment conditions; and
a hinge for use in a solar tracking apparatus that is easy to manufacture.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

The use of the expression “at least” or “at least one” suggests the use of one or more elements or ingredients or quantities, as the use may be in the embodiment to achieve one or more of the desired objects or results.

Any discussion of documents, acts, materials, devices, articles or the like that has been included in this specification is solely for the purpose of providing a context for the disclosure. It is not to be taken as an admission that any or all of these matters form part of the prior art base or were common general knowledge in the field relevant to the disclosure as it existed anywhere before the priority date of this application.

The numerical values mentioned for the various physical parameters, dimensions or quantities are only approximations and it is envisaged that the values higher/lower than the numerical values assigned to the parameters, dimensions or quantities fall within the scope of the disclosure, unless there is a statement in the specification specific to the contrary.

1. A hinge for solar tracking apparatus, said hinge comprising:
a first mounting plate having a pair of beveled or curved side faces;
a second mounting plate having a pair of beveled or curved side faces; and
a plurality of connecting elements adapted to connect said first mounting plate to said second mounting plate in a spaced apart configuration, wherein each of said plurality of connecting elements being adapted to connect diagonally opposite side faces of said first mounting plate to said second mounting plate,
wherein said hinge is adapted to facilitate said solar tracking apparatus to track the Sun.

2. The hinge as claimed in claim 1, wherein said side faces of said first mounting plate and said second mounting plate have a bevel angle of about 45°.

3. The hinge as claimed in claim 1, wherein diagonally opposite side faces of said first mounting plate and said second mounting plate have equal bevel angles.

4. The hinge as claimed in claim 1, wherein each of said first mounting plate and said second mounting plate comprises at least one mounting hole configured thereon for facilitating mounting thereof to other structural elements.

5. The hinge as claimed in claim 1, wherein each of said first mounting plate and said second mounting plate is of powder coated mild steel.

6. The hinge as claimed in claim 1, wherein each of said plurality of connecting elements is a thin discrete strip.

7. The hinge as claimed in claim 1, wherein each of said plurality of connecting elements has a frame structure.

8. A solar power generation system comprising:
a solar power converter adapted to convert solar energy into at least one other form of energy;
at least one hinge adapted to facilitate mounting of said solar power converter thereon, wherein each of said hinge comprising,
a first mounting plate having a pair of beveled or curved side faces;
a second mounting plate having a pair of beveled or curved side faces; and
a plurality of connecting elements adapted to connect said first mounting plate to said second mounting plate in a spaced apart configuration, wherein each of said plurality of connecting elements being adapted to connect diagonally opposite side faces of said first mounting plate to said second mounting plate; and
a solar tracking apparatus adapted to mount at least one hinge thereon, wherein said solar tracking apparatus is adapted to facilitate tracking of the Sun by means of said at least one hinge.

9. The solar power generation system as claimed in claim 8, wherein said solar power converter is a solar cell for generation of electricity.

10. The solar power generation system as claimed in claim 8, wherein said solar power converter is a concentrating system for generation of thermal power.
